(19) United States
(12) Patent Application Publication
(10) Pub. No.: US 2017/0309765 A1
(43) Pub. Date: Oct. 26, 2017

(54) INCREMENTAL SOLAR ANTENNA ARRAY FABRICATION

(71) Applicant: NovaSolix, Inc., Palo Alto, CA (US)

(72) Inventors: Laurence H. COOKE, Los Gatos, CA (US); Andreas HEGEDUS, Burlingame, CA (US)

(21) Appl. No.: 15/133,807

(22) Filed: Apr. 20, 2016

(51) Int. Cl. H01L 31/0465; H01L 31/028; H01L 31/044

(52) U.S. Cl. CPC H01L 31/0465; H01L 31/044; H01L 31/028

(57) ABSTRACT

A solar antenna array may comprise an array of antennas that may capture and convert sunlight into electrical power. Methods for constructing the solar antenna array may initially use range of semiconductor processing steps to minimize development costs, and may subsequently use a combination of stamps and low cost materials to reduce manufacturing costs. Designs may be optimized for capturing a broad spectrum of visible light and non-polarized light. Continuous flow Fabrication and Testing is also described.

### FIELD OF ENDEAVOR

Various aspects of this disclosure may pertain to an incremental economical series of manufacturing processes of visible light rectenna arrays for the conversion of solar energy to electricity.

### BACKGROUND

Rectifiers for AC to DC conversion of high frequency signals have been well known for decades. A particular type of diode rectifier when coupled to an antenna, called a Rectenna, has also been known for decades. More specifically, over 20 years ago, Logan described using an array of Rectennas to capture and convert microwaves into electrical energy in U.S. Pat. No. 5,043,739 granted Aug. 27, 1991. However, the dimensions of the antenna limited the frequency until recently, when Gritz, in U.S. Pat. No. 7,679,957 granted Mar. 16, 2010, described using a similar structure for converting infrared light into electricity, and Pietro Siciliano suggested that such a structure may be used for sunlight in “Nano-Rectenna For High Efficiency Direct Conversion of Sunlight to Electricity: by Pietro Siciliano of The Institute for Microelectronics and Microsystems IMM-CNR, Lecce (Italy).

Still, the minimum dimensions required for such visible light rectennas are generally in the tens of nanometers. While these dimensions may be accomplished by today's deep submicron masking technology, such processing is typically far more expensive than the current solar cell processes, which require much larger dimensions.

Still, as Logan pointed out in U.S. Pat. No. 5,043,739, the efficiency of microwave Rectennas can be as high as 40%, more than double that of typical single junction poly-silicon solar cell arrays, and when using metal-oxide-metal (MOM) rectifying diodes, as Pietro suggests, no semiconductor transistors are needed in the array core.

As such, it may be advantageous to be able to utilize the existing fine geometry processing capability of current semiconductor fabrication without incurring the cost of such manufacturing.

Also, recently, Rice University reported that their researchers created a carbon nanotube (CNT) thread with metallic-like electrical and thermal properties. Furthermore, carbon nanotube structures are becoming more manufacturable, as described by Rosenberger et al. in U.S. Pat. No. 7,354,977 granted Apr. 8, 2008. Various forms of continuous CNT growth may have also been contemplated, such as Lemaire et.al. repeatedly harvesting a CNT “forest” while it is growing in U.S. Pat. No. 7,744,793 granted Jun. 29, 2010, and/or put into practice using techniques described by Predtechensky et al. in U.S. Pat. No. 8,137,653 granted Mar. 20, 2012. Grigorian et al. describes continuously pushing a carbon gas through a catalyst backed porous membrane to grow CNTs in U.S. Pat. No. 7,431,985 granted Oct. 7, 2008.

Furthermore, others have contemplated using CNTs for various structures such as Rice University's CNT thread as described in “Rice's carbon nanotube fibers outperform copper,” by Mike Williams, posted on Feb. 13, 2014 at: news.rice.edu/2014/02/13/rices-carbon-nanotube-fibers-outperform-copper-2, magnetic data storage as described by Tyson Winarski in U.S. Pat. No. 7,687,160 granted Mar. 30, 2010, and in particular, antenna-based solar cells are described by Tadashi Ito et al. in US Patent Publication 2010/0244656 published Sep. 30, 2010. Still, Ito et al. did not describe methods to inexpensively construct carbon nanotube solar antennas for efficient conversion of solar energy.

### Summary of Various Embodiments

Various embodiments of the invention may relate to ways to manufacture structures of CNT rectenna arrays for converting sunlight into electricity, which may utilize molds made using current IC masking techniques and self-aligning process steps and to achieve the fine dimensions required for the antennas.

The structure of the rectenna array may include an array of CNT antennas connecting a ground plane to a negative voltage plane through metal oxide carbon (MOC) or metal insulator insulator carbon (MIIC) diodes. The antennas may be of varying lengths and orientations, distributed for maximum reception of the full spectrum of ambient sunlight. The small diameter CNTs connecting to the larger voltage plane may also form geometric diodes. Single ¼ wave length antenna diode combinations may half wave rectify the received light. Two coupled ¼ wave length antenna diode combinations may full wave rectify the received light.

The manufacture of these arrays may be incrementally modified to transfer from a low volume semiconductor related process to a high volume plastic based continuous flow process.

In one embodiment, the CNT antenna array manufacturing process may include depositing a mixture of a number metals, masking and etching on a silicon wafer to construct the necessary structures prior to growing CNT antennas.

In another embodiment, a stamp may be constructed to pattern resist for selectively etching the structures necessary to create the CNT antenna array. Alternatively the stamp may be used to directly pattern metal, and further used to pattern a drum for high volume continuous CNT antenna array manufacturing. The stamp may be created by a series of masked anisotropic V-groove etches with subsequent anti-adhesion depositions.

In yet another embodiment, a plastic base may be stamped and blade filled with a metal alloy to form bus bars. A thin layer of plastic may be deposited on the bus bars, and exposed vias of the plastic may be removed. The plastic assembly may thereafter be pressed to raise the bus bar metal up into the vias. A metal mixture may be deposited on the plastic assembly and patterned by a drum, which may be pressed into the metal, creating pads and ridges. The pads and ridges may be selectively etched to expose one of the metals. Oxide may be grown and selectively reduced prior to growing carbon nanotubes between the pads and ridges. Shorts may be removed and a plastic cover may be spun on after protective edges have been extruded, thereby forming a continuous roll of flexible solar cells.

### BRIEF DESCRIPTION OF THE DRAWINGS

Various embodiments of the invention will now be described in connection with the attached drawings, in which:

FIG. 1 is an electrical diagram of a combined diode and antenna according to an embodiment of the invention,

FIG. 2 is another electrical diagram of a pair of diodes and antennas according to an embodiment of the invention,

FIG. 3 is a logical diagram of an array of antennas and diodes according to an embodiment of the invention,

FIGS. 4 and 5 are diagrams of the cross-section of an antenna array depicting a single Diode and Carbon Nanotube Antenna according to embodiments of the invention,

FIG. 6 is a diagram of top view of a section of an array of antennas according to an embodiment of the invention,

FIGS. 7 through 12 are cross-sections of an antenna array during successive steps in manufacture according to an embodiment of the invention,

FIGS. 13 and 14 are cross-sections of a stamp during steps of its construction, according to an embodiment of the invention,

FIGS. 15,16 and 17 are cross-sections of antenna arrays during steps in manufacture according to embodiments of the invention,

FIG. 18 is an annotated cross-section of an antenna array, according to an embodiment of the invention,

FIG. 19 is a diagram of the top view of a section of an array of antennas according to another embodiment of the invention,

FIG. 20 is another diagram of the top view of a section of an array of antennas according to an embodiment of the invention,

FIGS. 21 through 32 are cross-sections of an antenna array during successive steps in high volume manufacturing according to an embodiment of the invention, and

FIG. 33 is a diagram of continuous flow process steps according to an embodiment of the invention.

### DESCRIPTION OF VARIOUS EMBODIMENTS

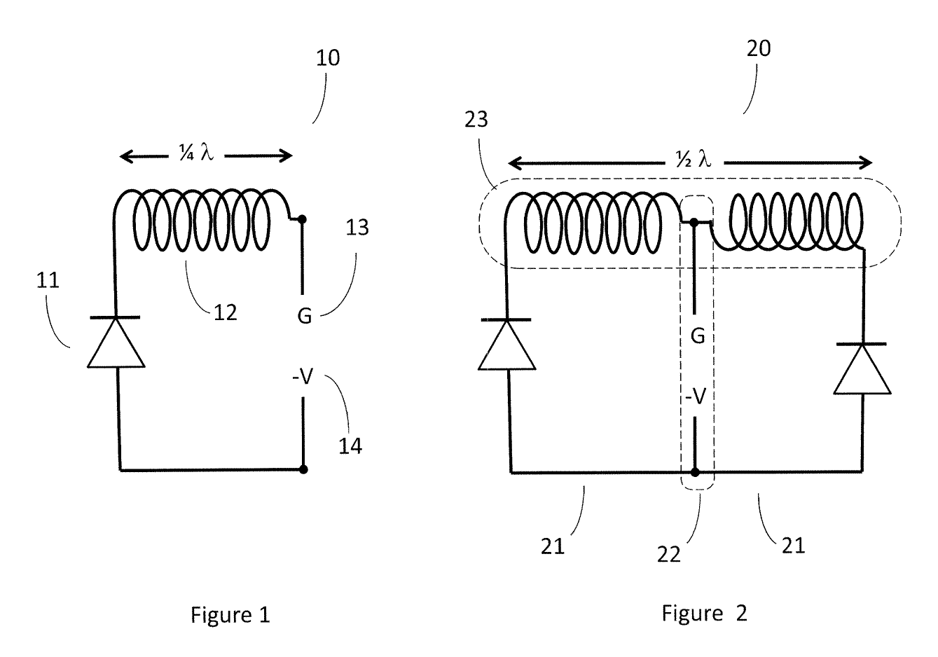

Embodiments of the present invention are now described with reference to FIGS. 1-33, it being appreciated that the figures may illustrate the subject matter of various embodiments and may not be to scale or to measure.

An electrical diagram 10 of a combined diode and antenna according to an embodiment of the invention is shown in FIG. 1. A diode 11 and a ¼ wavelength antenna 12 are coupled together with the antenna 12 further connected to a ground line 13 and the diode 11 connected to a −Voltage line 14, to form a ½ wave rectified structure. Another electrical diagram 20 of a pair of diodes and antennas according to another embodiment of the invention, is shown in FIG. 2. Two structures 21, each equivalent to the electrical diagram shown in FIG. 1, may be coupled to common Ground and −Voltage lines 22, to form a full wave rectified structure.

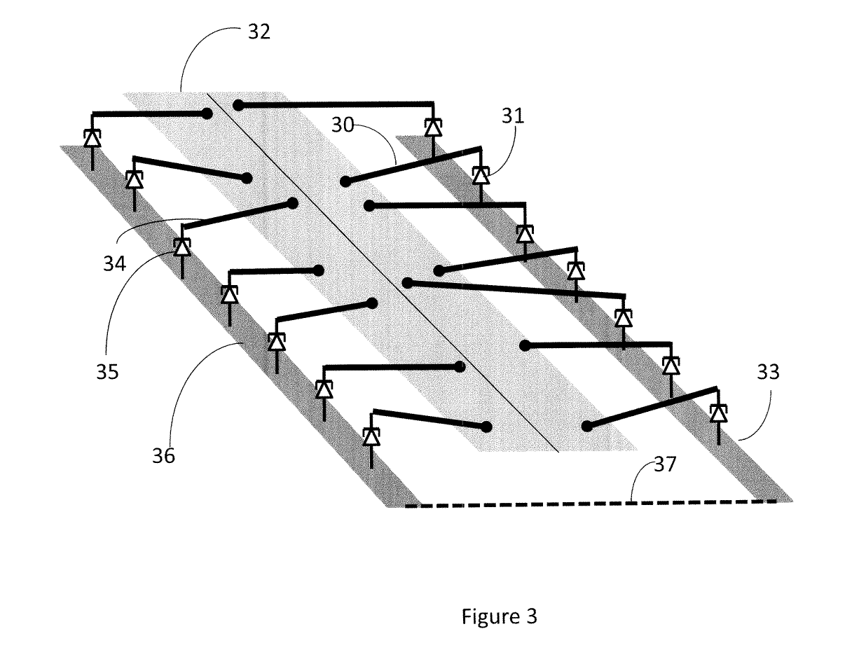

Reference is now made to FIG. 3, a logical diagram of an array of antennas and diodes according to an embodiment of the invention. The antenna 30 and diode 31 may be respectively connected to the ground plane 32 and the power plane 33 in a manner similar to the electrical diagram in FIG. 1. A second antenna 34 and diode 35 may be respectively connected to another side of the ground plane 32 and another power plane 36, which may in turn be connected 37 to the original power plane. Together the antennas 30,34 and diodes 31,35 may be connected to the power 33,36 and ground 32 planes in a manner similar to the electrical diagram in FIG. 2. The antennas may be of varying lengths and randomly placed between the diodes and the ground plane 32. The antennas may be metallic carbon nanotubes.

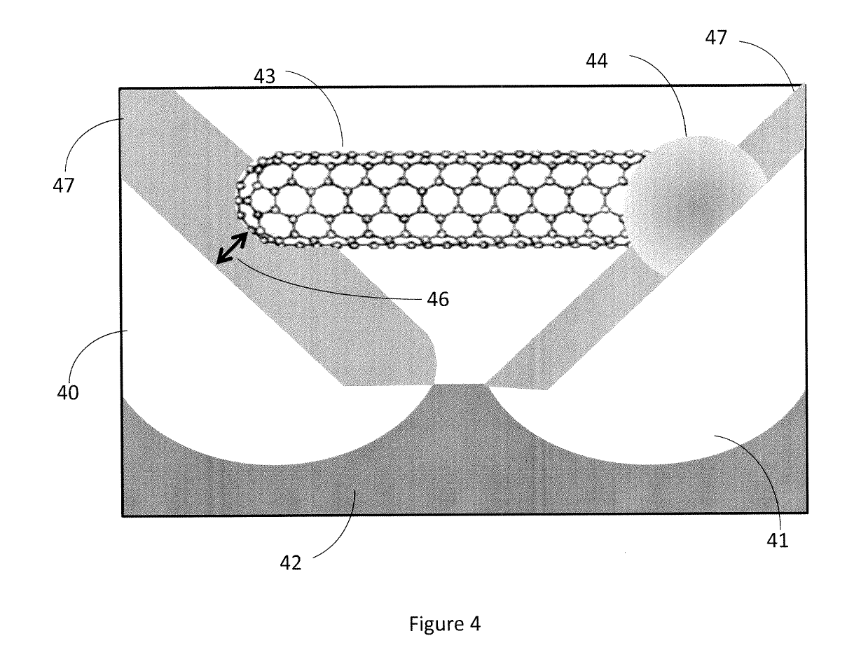

Reference is now made to FIG. 4, a diagram of the cross-section of an antenna array depicting a single Diode and CNT Antenna according to an embodiment of the invention. The antenna 43 may be either a single walled metallic carbon nanotube, or a multi-walled carbon nanotube, which may be attached to the ground plane 41 via a catalyst 44. The catalyst may be used to grow the CNT. The catalyst may be composed of Nickel, Iron, Cobalt, or some combination of the three, but is not necessarily thus limited. The tip of the carbon nanotube 43, coupled to oxide layer 47, may form a metal oxide carbon (MOC) diode 46 connected to the voltage plane 40. The power and ground planes may be insulated from each other via a base 42. The base 42 may be, e.g. a ceramic or a plastic material. The power 40 and ground 41 planes may be composed of one or more metals.

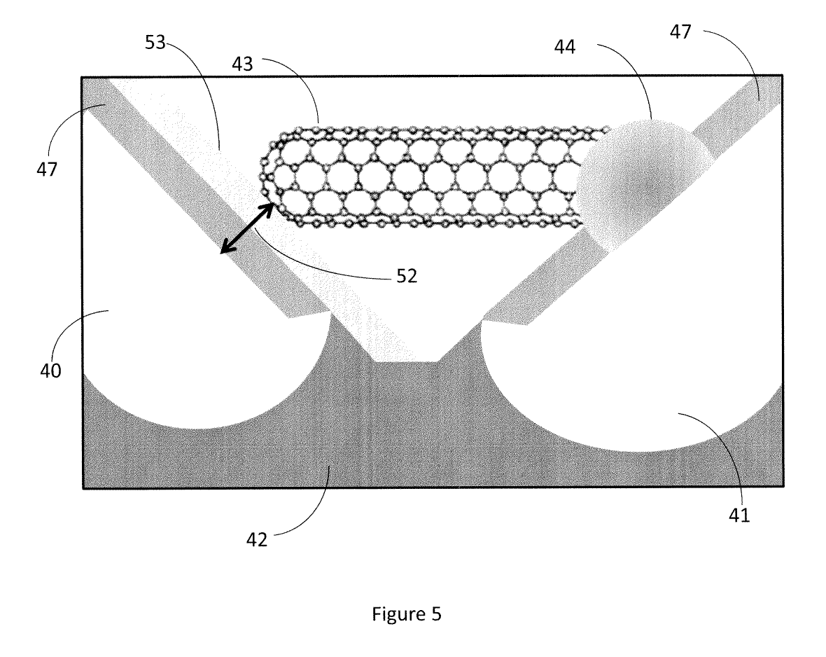

Reference is now made to FIG. 5, another diagram of the cross-section of an antenna array depicting a single Diode and CNT Antenna according to another embodiment of the invention. In this case a different oxide layer 53 may cover the original oxide layer to form a metal insulator insulator carbon (MIIC) diode 52 between the CNT 43 and the power plane 40.

In order to efficiently rectify visible light, the diodes must have a cutoff frequency above 700 THz. This may require diodes (46 or 52) with sufficiently small enough capacitance, which may be accomplished by growing diodes under 15 nanometers in diameter to oxides that are each a few nanometers thick. In addition to a MOC or MIIC diode, the small diameter of the CNT connecting to the large angled side of the power plane may form a geometric diode. Furthermore, the antenna lengths may vary in length and direction to cover the entire spectrum of un-polarized sun light. This may be accomplished by varying the distance the CNTs 43 must cover from the ground 41 plane to the power plane 40, from ¼ wave length of ultraviolet light (˜80 nanometers) to ¼ wave length of infrared light (˜640 nanometers).

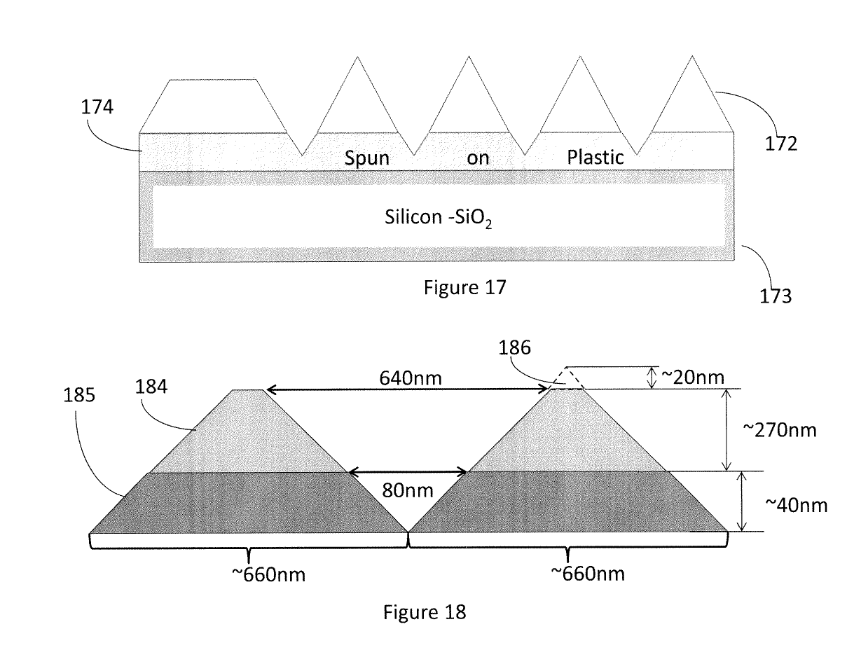

A series of ridges with surfaces that are angled away from each other, such as shown in FIG. 18, an annotated cross-section of an antenna array, according to an embodiment of the invention, may provide the structure necessary to create such varying lengths of CNTs. Each ridge may be composed of a metal top 184 over an insulating layer 185. Each ridge may be ˜310 nanometers tall, with a 660 nanometer base.

Such small structures may require the combination of complex semiconductor processing coordinated with controlled growth of Carbon Nanotube antennas. It may therefore be desirable to leverage as much of existing semiconductor processing as possible, and incrementally modify the process to reduce cost and increase volume. As such, an initial manufacturing process may rely on existing semiconductor mask and etching operations, and may gradually change to a continuous flow of maskless operations.

Reference is now made to FIG. 6, a diagram of top view of a section of an array of antennas according to an embodiment of the invention. This structure consists of large power 61 and ground 62 bus bars, with interleaved smaller power 64 and ground 63 fingers, with the CNT antennas spanning between adjacent power 66 and ground 67 fingers. The dimensions of the fingers may be similar to those seen in FIG. 18.

Semiconductor masking technology may consist of steppers and contact printers. Typically, steppers can print very fine geometries, such as the fingers above, but can only expose a small part of the die at a time. On the other hand, contact printers expose the whole wafer at one time, but can only align and print very large objects. In order to construct a wafer-wide array of the structure shown in FIG. 6, it may be necessary to make the spacing between the fingers 67 be sufficiently larger than the bus bar 62 to allow for the alignment error. The contact printing of the bus bars may then be done first, followed by the stepper printing of the fingers.

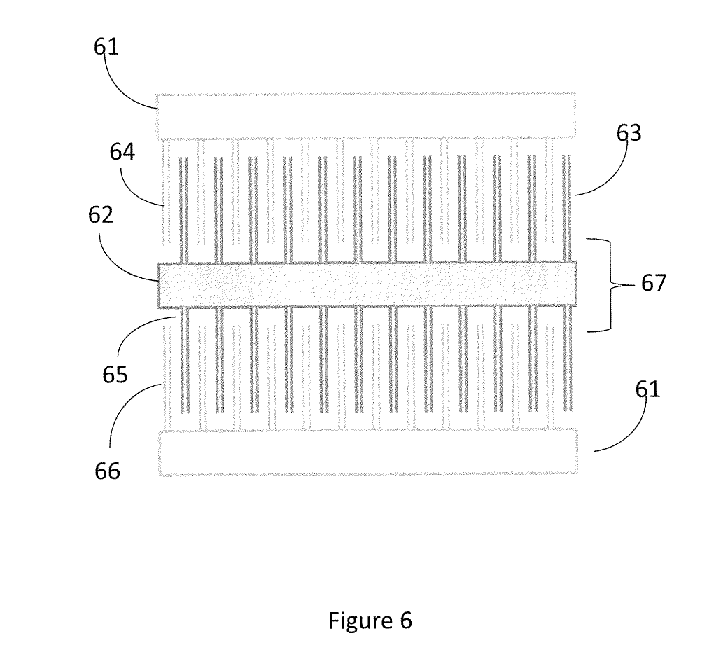

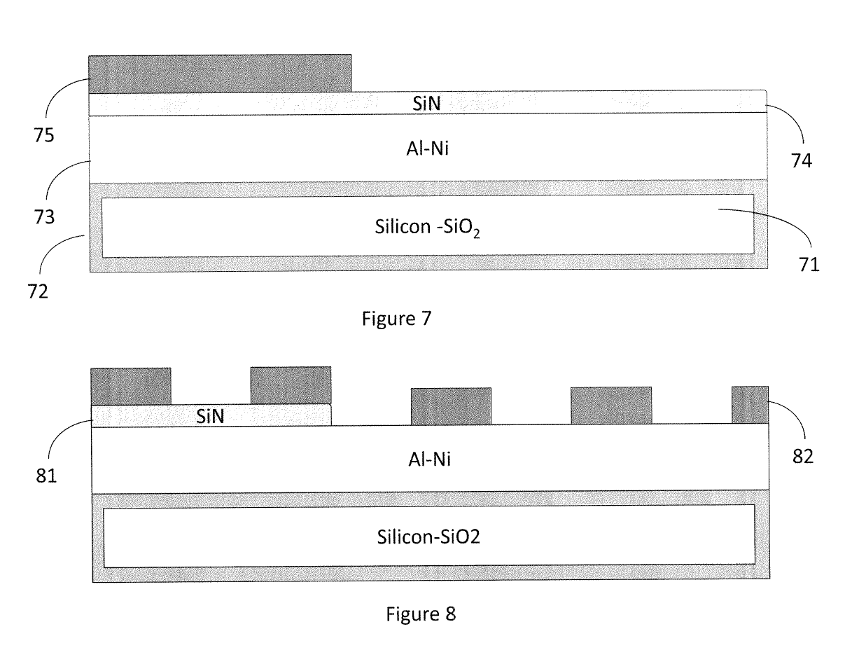

Reference is now made to FIGS. 7 and 8, cross-sections of an antenna array during successive steps in manufacture according to an embodiment of the invention. Initially a base may be created by adding thermal oxide 72 on a silicon wafer 71. Alternatively a glass or quartz plate may be used. A hard mask layer 74 may then be deposited over a previously deposited layer of metal 73 on the base. A full wafer contact mask may expose resist 75, which may be used to selectively etch the hard mask layer 81, exposing the finger area. The stepper pattern may then expose finer dimensioned resist 82. The metal layer 73 may be an amorphous layer of Aluminum and Nickel, and the hard mask layer 81 may be a thin layer of Silicon Nitride, or Silicon Oxide.

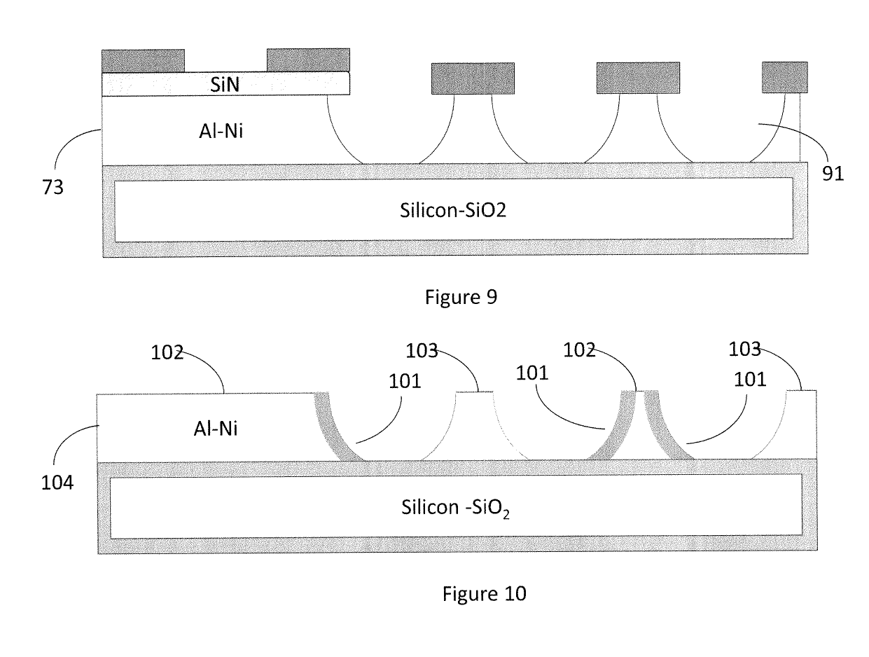

Reference is now made to FIGS. 9 and 10, cross-sections of an antenna array during further steps in manufacture according to an embodiment of the invention. By over etching using an isotropic etch, rounded curves 91 may be created in the metal layer 73. The hard mask layer may then be selectively etched exposing the metal bus bars 104. Since the structures are now electrically isolated, it may be possible to apply a bias voltage on every other finger 102 and ground on the other fingers 103. In a reactive ion etch step, the bias voltage may attract ions to selectively remove a portion of the metal, exposing a remaining unetched second metal 101. The ions may be chlorine, which selectively etches Aluminum leaving Nickel unetched.

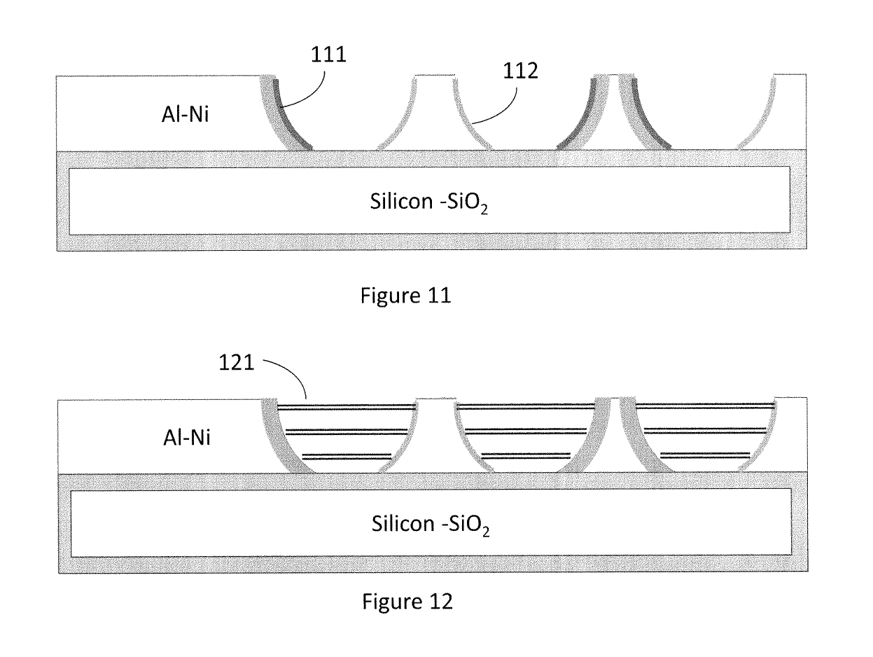

Reference is now made to FIGS. 11 and 12, cross-sections of an antenna array during further steps in manufacture according to an embodiment of the invention. By exposing the antenna array to oxygen, a Nickel oxide layer 111 may form on the Nickel and an Aluminum oxide layer 112 may form on the Aluminum-Nickel composite. Typically the ratio of Aluminum to Nickel may be high enough such that the Aluminum oxide layer 112 completely covers the Nickel. Thereafter by again applying a bias voltage to every other finger, the Nickel oxide may be removed without removing the Aluminum Oxide. CNTs 121 may then be grown under another bias from the Nickel catalyst to the Aluminum Oxide, thereby creating the diodes and antennas of varying lengths to rectify varying wavelengths of sunlight.

While this process may be easily created using existing semiconductor processing equipment, the end product may be too expensive. In order to reduce the manufacturing cost, the masking steps may be replaced with some stamping process.

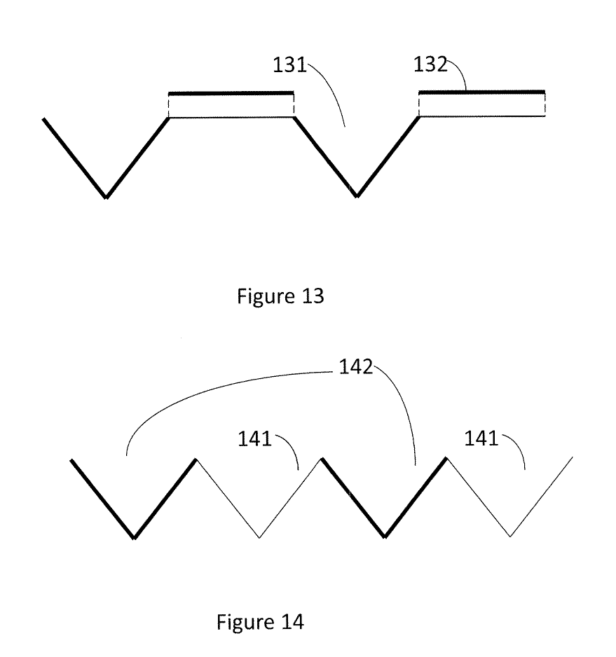

Reference is now made to FIGS. 13 and 14, cross-sections of a stamp during steps of its construction, according to an embodiment of the invention. An anisotropic etch of a silicon wafer may be used to produce V-grooves, by masking 660 nanometer wide sections. Then, a thin layer of non-adhesive material may be deposited in the V-grooves 131 and on the resist 132. Removing the resist exposes the Silicon between the V-grooves. The thin layer of non-adhesive material 142 may form an etch stop to produce additional V-grooves 141, which may also be covered with a thin non-adhesive material. Initially these wafer sized stamps may be used to stamp patterns on the antenna arrays, which may thereby eliminate the masking steps.

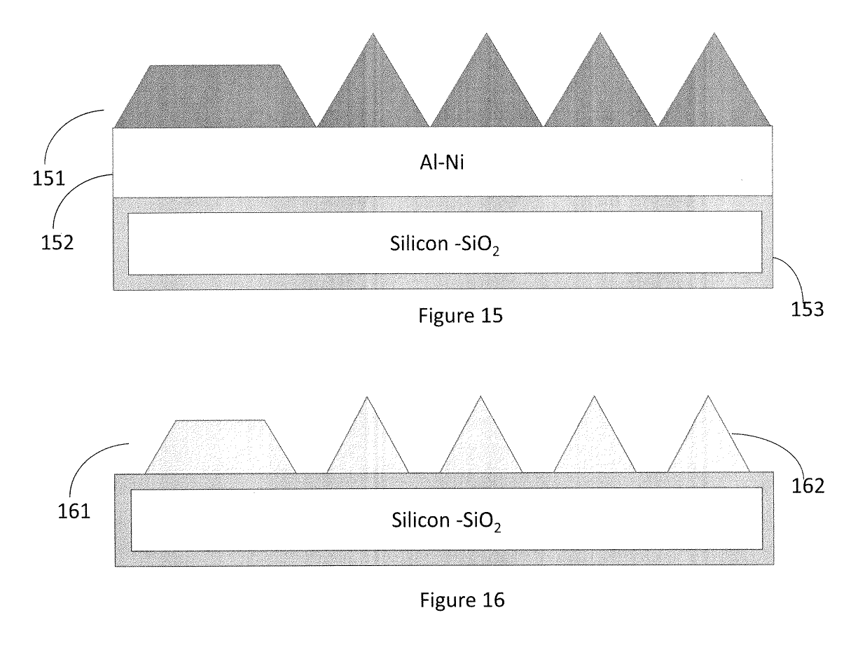

Reference is now made to FIGS. 15 and 16, cross-sections of a antenna arrays during steps in manufacture according to another embodiment of the invention. In this case the mask steps may be replaced by stamping the layer of resist 151 above the deposited metal 152 on the base 153. The pattern stamped into the resist may then be transferred to the underlying metal by performing an anisotropic etch sufficient enough to isolate the ridges 162 from each other and the bus bar 161.

Reference is now made to FIG. 17, a cross-section of an antenna array during manufacture according to yet another embodiment of the invention. To further reduce the material cost of the manufacturing, it may be desirable to directly stamp the deposited metal. This may be done by spinning a thin layer of plastic 174 on the base 173. The wafer stamp may then be used to stamp the metal 172, creating electrically separated ridges by stamping into the plastic. The stamp may require different anti-adhesion materials for the metal than the resist. The anti-adhesion layer for the metal may be Silicon carbide or Silicon Nitride. When performing the stamping, it may be necessary to apply some combination of ultrasound of varying frequency and intensity in one, two or all three axes. Furthermore the high frequency movement may be synchronized to eliminate adhesion of the metal to the stamp. Alternatively, a thin layer of sacrificial material may be deposited on the stamp, promoting anti-adhesion of the metal, which may thereafter be removed. The sacrificial material may be a hydrocarbon compound, which may be removed from the metal with a solvent.

Still, in order to improve the efficiency of the antenna array and further reduce its manufacturing cost, it may be necessary to embed the bus bars, allowing more top surface area to be filled with antennas.

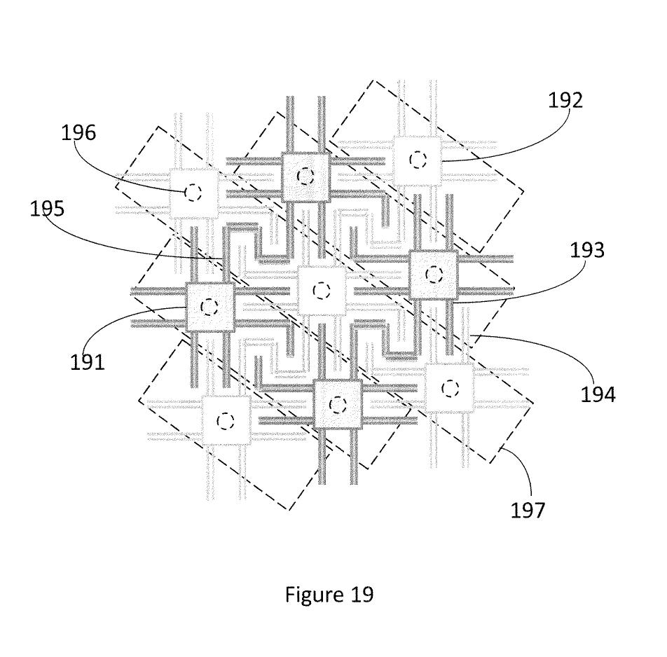

Reference is now made to FIG. 19, a diagram of the top view of a section of an array of antennas according to another embodiment of the invention. In this embodiment, the bus bars 197 may be buried under the ground fingers 193 and/or voltage fingers 194, and may be connected to respective ground pads 191 and voltage pads 192 with vias 196. The CNT antennas may span between the fingers (193 and 194). There may be at least one finger connection 195 between pads to allow for testing. This drawing is for illustration purposes. Less than 1% of the space in the actual design, may be taken up by the pads and vias, and the lines may zig-zag to allow for all orientations of antennas.

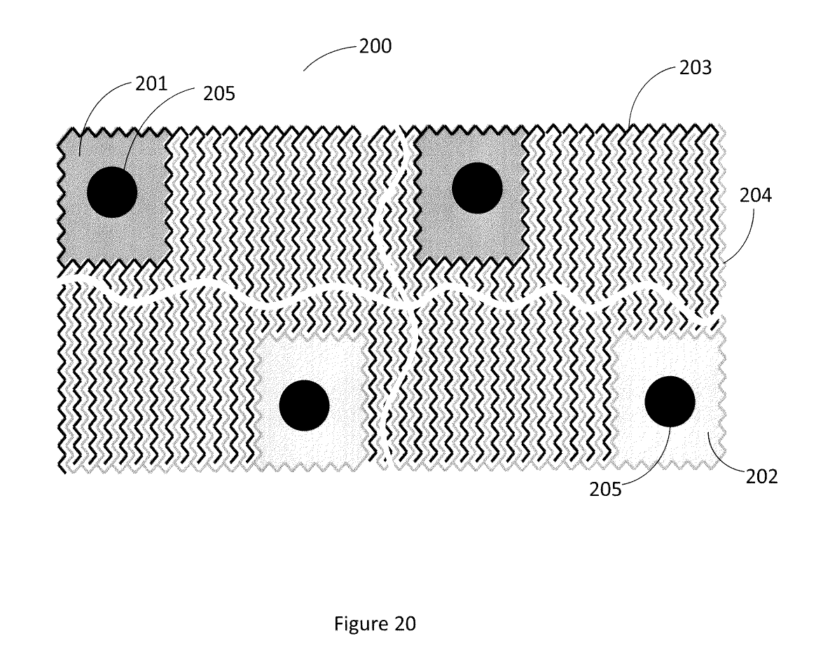

Reference is now made to FIG. 20, another diagram of the top view of a section of an array of antennas according to an embodiment of the invention. This diagram illustrates one way to zig-zag the ground 203 and power 204 fingers.

In order to further minimize the cost of high volume antenna array manufacturing, it may be necessary to
a) Minimize the material costs by replacing silicon or glass with plastic,
b) Replace masking steps with continuous laser pulsing or drum type stamps, and
c) Replace wafer-by-wafer processing with continuous roll processing.

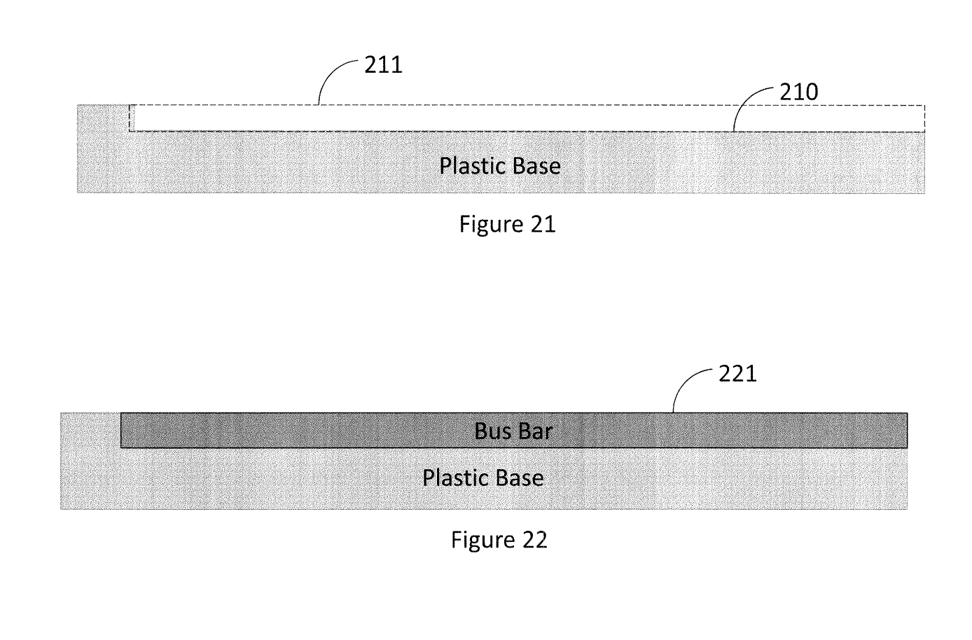

Reference is now made to FIGS. 21 and 22, cross-sections of an antenna array during successive steps in high volume manufacture according to an embodiment of the invention. Starting with a plastic base 210, fed from a roll of plastic (not shown), a drum stamp may create depressions in the plastic by applying rolling pressure on the plastic, which may then be filled with bus bar metal 221 by blade flowing the metal into the stamped depressions. The bus bar metal may be, e.g., Copper, Aluminum or an Aluminum copper alloy. As depicted in FIG. 19, the bus bars may alternate between ground and negative voltage planes, and may span the diagonal distance of the plastic roll.

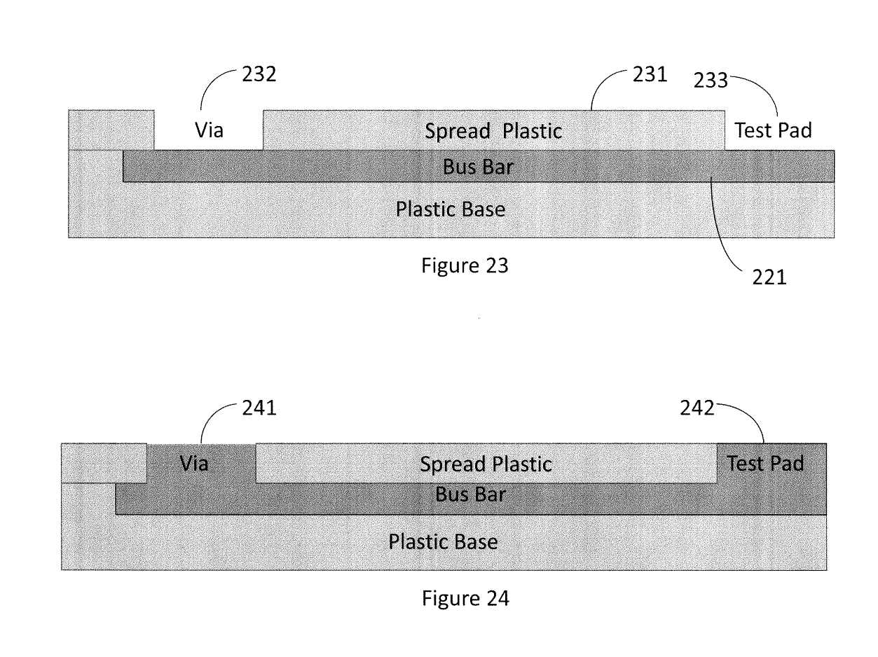

Reference is now made to FIGS. 23 and 24, cross-sections of an antenna array during further steps in high volume manufacture according to an embodiment of the invention. A plastic layer 231 may be blade spread over the bus bars 221. Test pads 233 and vias 232 may be laser exposed and removed. A flat drum may press the partially cured bus bars to fill the Test pads 242 and vias 241. Note that, the laser operations may operate continuously, requiring as many lasers as necessary to expose all vias in the scanning time and space allotted by the continuous flow.

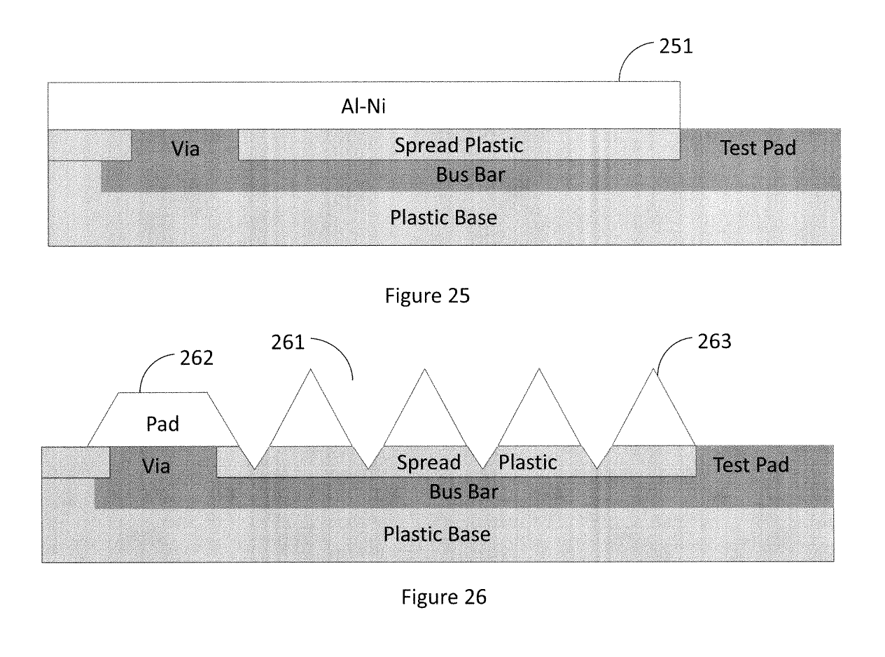

Reference is now made to FIGS. 25 and 26, cross-sections of an antenna array during further steps in high volume manufacture according to an embodiment of the invention. A metal composite 251 may then be deposited on the plastic, and subsequently stamped with a drum stamp, which may also require ultrasound vibration in one or more axes. As in the wafer based case, the stamp separates the metal structures by stamping into the plastic 261. A short post stamp clean or etch may be required to eliminate any shorts between the pads 262 and the ridges 263. Note that, these process steps may be performed in a lower pressure environment, which may require a pump-down prior to these steps in the continuous flow.

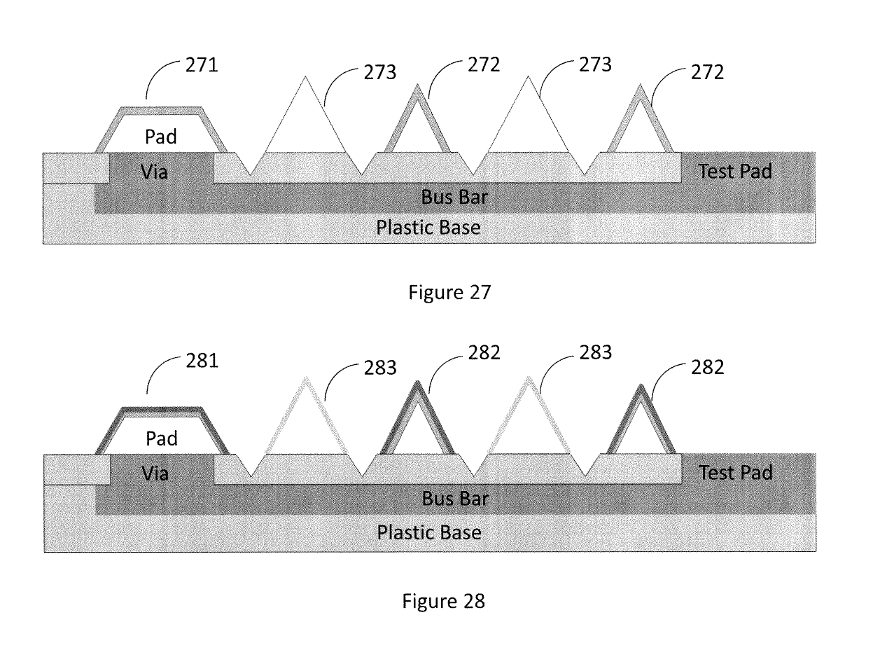

Reference is now made to FIGS. 27 and 28, cross-sections of an antenna array during further steps in high volume manufacture according to an embodiment of the invention. In these steps, the electrically isolated ridges and pads may be set to ground; and a bias voltage may be applied to selectively remove aluminum, exposing the residual nickel on the ground pads 271 and fingers 272, while leaving the aluminum on the power fingers 273. As with the wafer-based process the Nickel and Aluminum may be oxidized, leaving layers of Nickel oxide 281,282 and Aluminum oxide 283 over the pads and ridges.

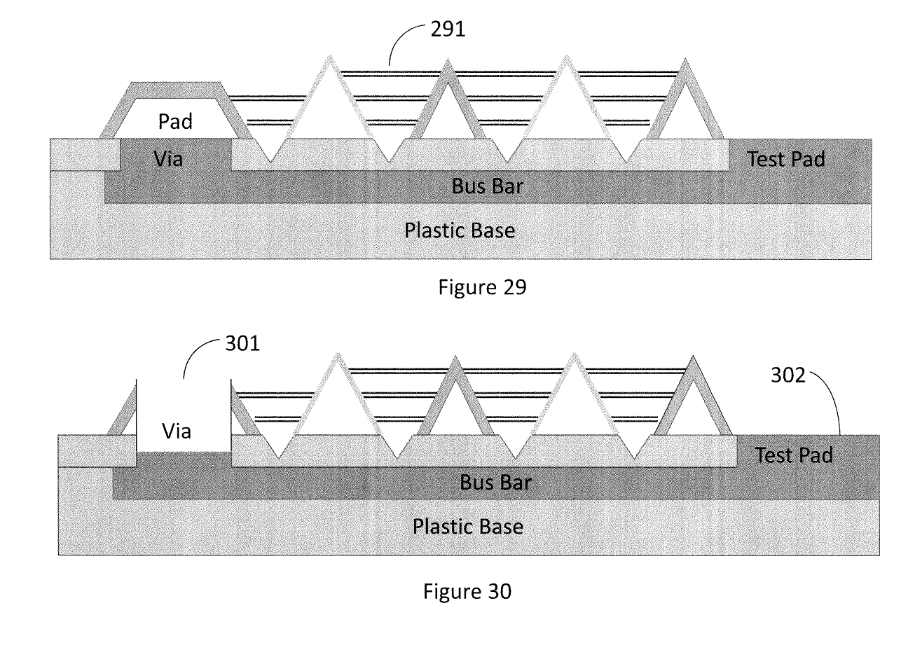

Reference is now made to FIGS. 29 and 30, cross-sections of an antenna array during further steps in high volume manufacture according to an embodiment of the invention. In a manner similar to the wafer process, prior to the CNT growth, the Nickel oxide may be selectively reduced. Then the CNTs 291 may be grown, followed by a pump up to normal atmosphere. The test pads 302 may now be used to test for shorts, and the vias of shorted structures may be removed 301, e.g., by laser vaporization of the metal vias to the shorted structures. Continuous testing may be done by rolling sprockets, which may simultaneously contact multiple ground and negative voltage bus bars, and check for shorting current between them. Specific pads may be isolated by testing through the perpendicularly diagonal finger connections as depicted in element 195 of FIG. 19 in conjunction with the bus bars. The profile of resistances along successive bus bars may determine the location of the specific pads.

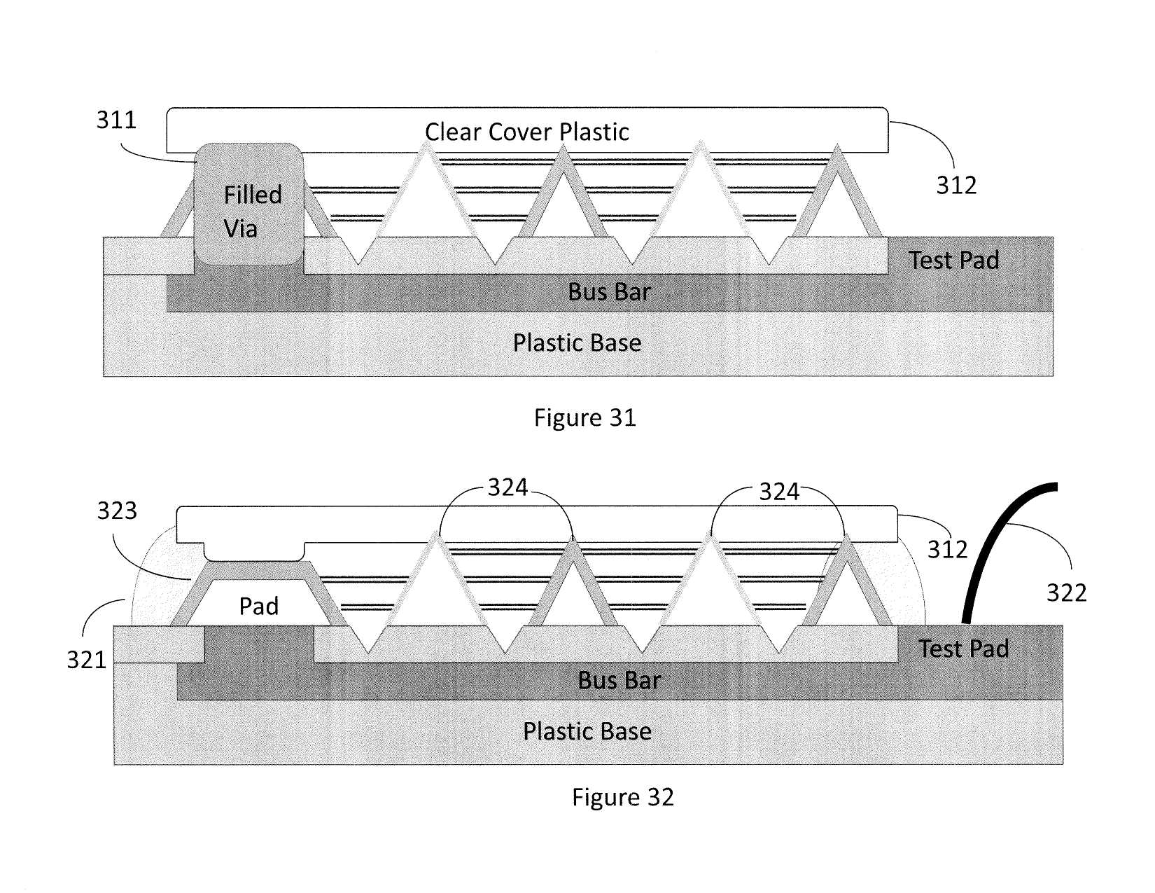

Reference is now made to FIGS. 31 and 32, cross-sections of an antenna array during further steps in high volume manufacture according to an embodiment of the invention. Following test and repair, the removed vias may be filled with a plastic 311, and the entire array may be covered in a clear plastic 312. Individual panels may then be cut from the roll, sealed 321, and wire bond attached to inverters and other electrical devices 322. The filled vias 311 and the good pads 323, along with the tops of the ridges 324 may all support the cover plastic 312, leaving air gaps that may be filled with a chemically inert gas that may act as a dielectric material for the antennas.

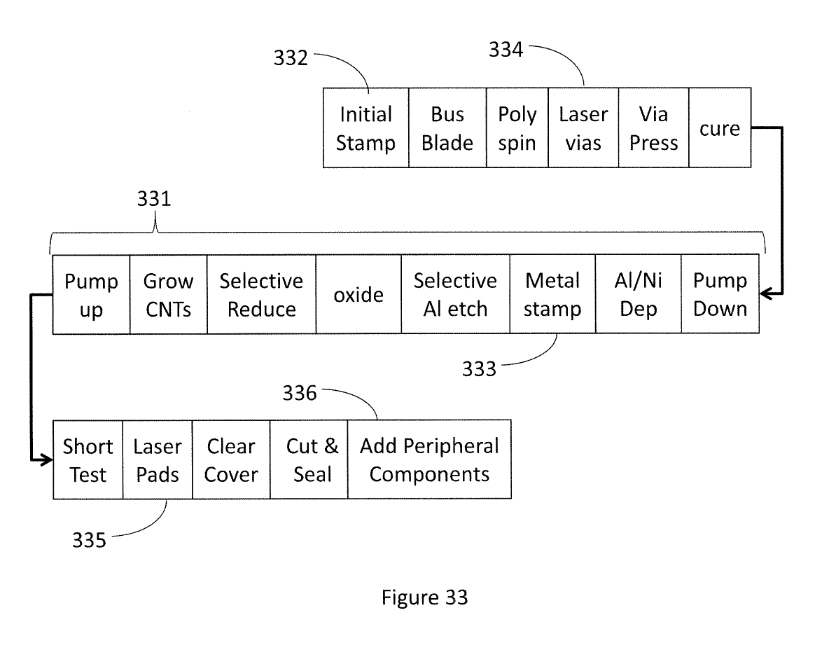

Furthermore, it may be understood by one well-versed in the state of the art that additional circuitry, such as switching and decoupling capacitors, may be included in the periphery of the solar antenna array, as may be desired to produce stable DC power in voltages suited for commercial applications, depicted as 336 in FIG. 33.

Reference is now made to FIG. 33, a diagram of continuous flow process steps according to an embodiment of the invention. The process may begin with a roll of plastic and may end either with a roll of finished panels, or a stack of individually cut plastic panels. To reduce cost, all the low atmosphere steps may be done within one pump down 331, and all masking steps may be replaced with stamping 332,333 or lasers 334,335.

It will be appreciated by persons skilled in the art that the present invention is not limited by what has been particularly shown and described hereinabove. Rather the scope of the present invention includes both combinations and sub-combinations of various features described hereinabove as well as modifications and variations which would occur to persons skilled in the art upon reading the foregoing description and which are not in the prior art.

1. A solar antenna array configured to convert sunlight into electrical energy comprising:
a plurality of ground lines;
a plurality of voltage lines;
a plurality of carbon nanotube antennas; and
a plurality of diodes, wherein each diode comprises a combination of a geometric diode in series with a second diode;
wherein a respective antenna is coupled to a ground line and a diode, wherein a respective diode is coupled to a voltage line, and
wherein the antennas vary in length and orientation.

2. The solar antenna array in claim 1, wherein the second diodes are metal oxide carbon diodes.

3. (canceled)

4. The solar antenna array in claim 1, wherein the second diodes are metal insulator insulator carbon diodes.

5. (canceled)

6. (canceled)

7. A solar antenna array configured to convert sunlight into electrical energy comprising:
a plurality of ground lines;
a plurality of voltage lines;
a plurality of carbon nanotube antennas, each coupled to a ground line and a voltage line; and
a plurality of geometric diodes, each formed by tips of the carbon nanotube antennas coupled to respective voltage lines;
wherein the antennas vary in length and orientation.

8. The solar antenna array of claim 1, wherein at least one of the geometric diodes is formed by a tip of one of the plurality of carbon nanotube antennas coupled to a respective one of the plurality of voltage lines.
